(19) United States
(12) Patent Application Publication
(10) Pub. No.: US 2016/0118395 A1
(43) Pub. Date: Apr. 28, 2016

(54) SEMICONDUCTOR DEVICE AND METHOD OF FABRICATING THE SAME

(71) Applicant: SK hynix Inc., Gyeonggi-do (KR)

(72) Inventors: Chang Man SON, Gyeonggi-do (KR); Go Hyun LEE, Gyeonggi-do (KR)

(21) Appl. No.: 14/678,625

(22) Filed: Apr. 3, 2015

(30) Foreign Application Priority Data
Oct. 24, 2014 (KR) 10-2014-0145289

(51) Int. Cl. H01L 27/115; H01L 27/02

(52) U.S. Cl. CPC H01L 27/11578; H01L 27/0207

(57) ABSTRACT

A semiconductor device and a method of fabricating the same are disclosed. The semiconductor device includes a pipe gate, a multi-layered word line formed over the pipe gate, a first channel including a first pipe channel buried in the pipe gate and a first side channel coupled to both sides of the first pipe channel to pass through the word line, a second channel including a second pipe channel buried in the pipe gate and disposed over the first pipe channel and a second side channel coupled to both sides of the second pipe channel to pass through the word line, and an insulation pattern disposed between the first pipe channel and the second pipe channel.

### CROSS-REFERENCE TO RELATED APPLICATION

This application claims priority of Korean patent application No. 10-2014-0145289, filed on 24 Oct. 2014, the disclosure of which is hereby incorporated in its entirety by reference.

### BACKGROUND OF THE INVENTION

Embodiments of the present invention relate to a semiconductor device and a method of fabricating the same and, more particularly, to a three-dimensional (3D) flash memory device and a method of fabricating the same.

Semiconductor memory devices have been developed to have high integration and store large amounts of data. A memory device that is formed on a single plane of a semiconductor substrate is called a two-dimensional (2D) memory device. In a two-dimensional (2D) memory device, improvement of integration is limited by the area of the substrate, resulting in memory elements being formed closer and closer together. As a result, it is becoming more difficult to implement multi-level cell (MLC) operation due to electrical coupling and other unwelcome phenomena. To overcome the limitations of two-dimensional (2D) memory devices, three-dimensional (3D) memory devices are being developed.

Three-dimensional (3D) memory devices include channels and stacked memory cells that are arranged perpendicular to the semiconductor substrate. Accordingly, three-dimensional (3D) memory devices are more effective in achieving high integration and large capacity than two-dimensional (2D) memory devices.

As the integration of 3D memory devices increases, adjacent channel regions become closer to each other so that the distance between adjacent channel regions is gradually reduced. As a result, a coupling phenomenon occurs between the channels, and parasitic capacitance also increases between the channels.

### BRIEF SUMMARY OF THE INVENTION

Various embodiments of the present invention are directed to a semiconductor device and a method of fabricating the same that improve the prior art in one or more ways.

An embodiment of the present invention relates to a semiconductor device in which an insulation material is inserted between adjacent pipe channels so that a coupling phenomenon generated between the adjacent pipe channels is suppressed and parasitic capacitance is reduced, and a method of fabricating the semiconductor device.

In accordance with an aspect of the present invention, a semiconductor device includes: a pipe gate; a plurality of word lines vertically stacked over the pipe gate; a first channel including a first pipe channel buried in the pipe gate, and a first side channel coupled to both sides of the first pipe channel by passing through the word lines; a second channel including a second pipe channel buried in the pipe gate and disposed over the first pipe channel, and a second side channel coupled to both sides of the second pipe channel by passing through the word lines; and an insulation pattern disposed between the first pipe channel and the second pipe channel, which are vertically adjacent from each other.

The Insulation pattern may extend parallel to the word lines.

The insulation pattern may be formed over an entire region of the pipe gate.

The first pipe channel and the second pipe channel may be arranged such that the center point of the first pipe channel and the center point of the second pipe channel are offset from each other.

The first pipe channel and the second pipe channel may have different critical dimension (CD) values in a direction of a major axis.

The semiconductor device may further include: a source selection line and a drain selection line formed over the word lines.

The semiconductor device may further include: a source line coupled to the source selection line at an upper portion of the source selection line.

The semiconductor device may further include: a bit line formed over the source line.

The first side channel disposed at one side of the first channel and the second side channel disposed at one side of the second channel may be coupled to different bit lines.

The first side channel disposed at the other side of the first channel and the second side channel disposed at the other side of the second channel may be coupled to a source line.

The Insulation pattern may be formed of an oxide film or an air-gap.

The word lines are formed by repeatedly stacking an insulation film and a conductive film.

It is to be understood that both the foregoing general description and the following detailed description of embodiments are exemplary and explanatory.

### BRIEF DESCRIPTION OF THE DRAWINGS

FIG. 1 illustrates a layout of a semiconductor device according to an embodiment.

FIG. 2 is a perspective view illustrating a semiconductor device according to an embodiment.

FIG. 3 is a circuit diagram illustrating a semiconductor device according to an embodiment.

FIGS. 4A to 4H are cross-sectional views illustrating a method of fabricating a semiconductor device according to an embodiment.

FIGS. 5A to 5F are cross-sectional views illustrating a method of fabricating a semiconductor device according to another embodiment.

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts. In the following description, a detailed description of related known configurations or functions incorporated herein will be omitted when it may make the subject matter less clear.

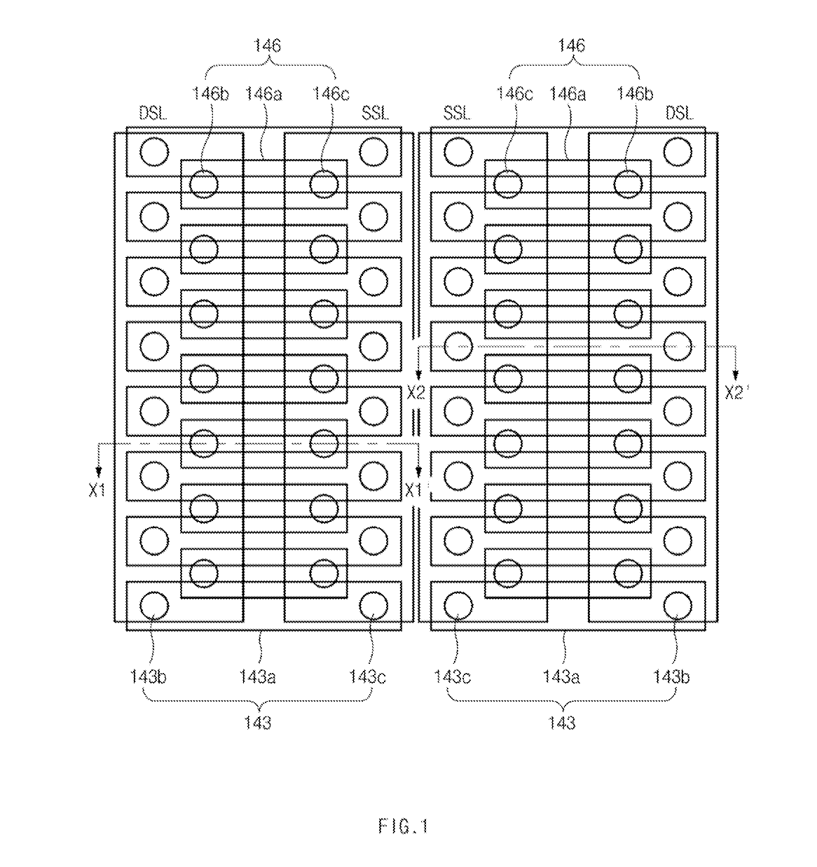

FIG. 1 illustrates a layout of a semiconductor device according to an embodiment.

Referring to FIG. 1, a first pipe channel 143a and a second pipe channel 146a are arranged in such a manner that each center point is offset by a predetermined distance. For example, the second pipe channel 146a may be located between the adjacent first pipe channels 143a neighboring with each other in a direction perpendicular to a line X1-X1′, and the first pipe channel 143a and the second pipe channel 146a may partially overlap with each other. Likewise, the center point of the first pipe channels 143a and the center point of the second pipe channels 146a are offset from each other. As a result, integration of the semiconductor device may increase. The first pipe channel 143a and the second pipe channel 146a have different critical dimension (CD) values in the direction of the line X1-X1′, i.e., a major axis.

In addition, drain selection lines DSL coupled to a first drain side channel 143b and a second drain side channel 146b are arranged at one side of the first pipe channel 143a and the second pipe channel 146a. Source selection lines SSL coupled to a first source side channel 143c and a second source side channel 146c are arranged at the other side of the first pipe channel 143a and the second pipe channel 146a.

The first pipe channel 143a, the first drain side channel 146b, and the first source side channel 143c may configure a first channel 143. The second pipe channel 146a, the drain side channel 147b, and the second source side channel 146c may configure a second channel 146. Since word lines and selection lines coupled to the first and second channels 143 and 146 that make one pair are formed as a single pattern, the word lines and the selection lines of the semiconductor device according to an embodiment are formed to have a larger width than those of the conventional art, so the stacked patterns are prevented from leaning.

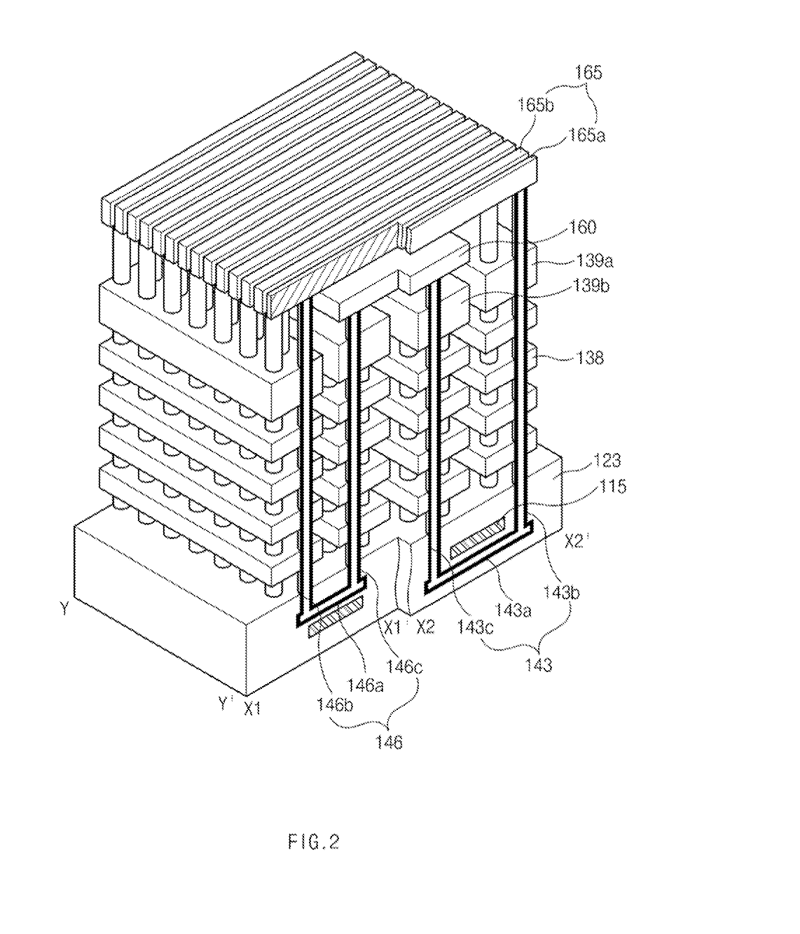

FIG. 2 is a perspective view illustrating a semiconductor device according to an embodiment. FIG. 2 illustrates a three-dimensional (3D) non-volatile memory device having the same layout as that of FIG. 1. FIG. 2 shows a cross-sectional view taken along the line X1-X1′ of the semiconductor device based on the second channel 146, and shows a cross-sectional view taken along a line X2-X2′ of the semiconductor device based on the first channel 143.

Referring to FIG. 2, the three-dimensional (3D) non-volatile memory device may include a pipe gate 123, first channels 143, second channels 146, word lines 138, drain selection lines (DSLs) 139a, source selection lines (SSLs) 139b, source lines (SLs) 160, and bit lines (BLs) 165.

Each of the first channels 143 includes a first pipe channel 143a buried in the pipe gate 123, and a first drain side channel 143b and a first source side channel 143c respectively coupled to one side and the other side of the first pipe channel 143a.

Each of the second channels 146 includes a second pipe channel 146a which is buried in the pipe gate 123 and formed over the first pipe channel 143a, a second drain side channel 146b and a second source side channel 146c respectively coupled to one side and the other side of the second pipe channel 146a. In this embodiment, an insulation pattern 115 may be disposed between the first pipe channel 143a and the second pipe channel 146b, which are vertically adjacent from each other. The insulation pattern 115 may extend parallel to the word lines 138. The insulation pattern 115 may be formed of an oxide film or air-gap. The oxide film may be formed of a Spin On Dielectric (SOD) film or an Undoped Silicate Glass (USG) film, a Phosphorus Silicate Glass (PSG) film, a Boron Phosphorus Silicate Glass (BPSG) film, or a combination thereof.

Although this embodiment has an insulation pattern 115 having a pattern shape for convenience of description and better understanding of the present invention, the scope or spirit of the present invention is not limited thereto. For example, the insulation pattern 115 interposed between the first pipe channel 143a and the second pipe channel 146b may be formed as a single layer over an entire region of the pipe gate 123. By applying a ground voltage (VSS) to the insulation pattern 115, this embodiment of the present invention may suppress a coupling phenomenon generated between the first pipe channel 143a and the second pipe channel 146a that are adjacent to each other with the insulation pattern 115 interposed therebetween, and may reduce parasitic capacitance.

The word lines 138 extending parallel in the Y-Y′ direction are vertically stacked over the pipe gate 123.

In this case, the word lines 138 may surround the first drain side channel 143b of the first channels 143 and the second drain side channel 146b of the second channels 146. In addition, the word lines 138 may surround the first source side channel 143c of the first channels 143 and the second source side channel 146c of the second channels 146. That is, the first drain side channel 143b and the second drain side channel 146b are formed by passing through the word lines 138, and the first source side channel 143c and the second source side channel 146c are formed by passing through the word lines 138.

The drain selection lines (DSLs) 139a and the source selection lines (SSLs) 139b extending parallel to the word lines 138 are formed over the word lines 138. In this case, the drain selection lines (DSLs) 139a may surround the first drain side channel 143b of the first channels 143 and the second drain side channel 146b of the second channels 146. In addition, the source selection lines (SSLs) 139b may surround the first source side channel 143c of the first channels 143 and the second source side channel 146c of the second channels 146.

The source lines (SLs) 160 extending parallel to the word lines 138 are formed over the source selection lines (SSLs) 139b. The source lines (SLs) 160 may be coupled to the source selection lines (SSLs) 139b at an upper portion of the source selection lines (SSLs) 139b. The source lines (SLs) 160 may be coupled to the first source side channel 143c of the first channel 143 and the second source side channel 146c of the second channel 146.

In addition, the bit lines (BLs) 165 extending parallel to the directions X1-X1′ and X2-X2′ are formed over the source lines (SLs) 160. In this case, the first channel 143 and the second channel 146 are coupled to different bit lines (BLs) 165. For example, the first drain side channels 143b of the first channels 143 may be coupled to a first bit line 165a, and the second drain side channels 146b of the second channels 146 may be coupled to a second bit line 165b.

As described above, the insulation pattern 115 is inserted between the first pipe channel 143a and the second pipe channel 146a, which are vertically adjacent from each other, so that the coupling phenomenon generated therebetween is suppressed and the parasitic capacitance is reduced.

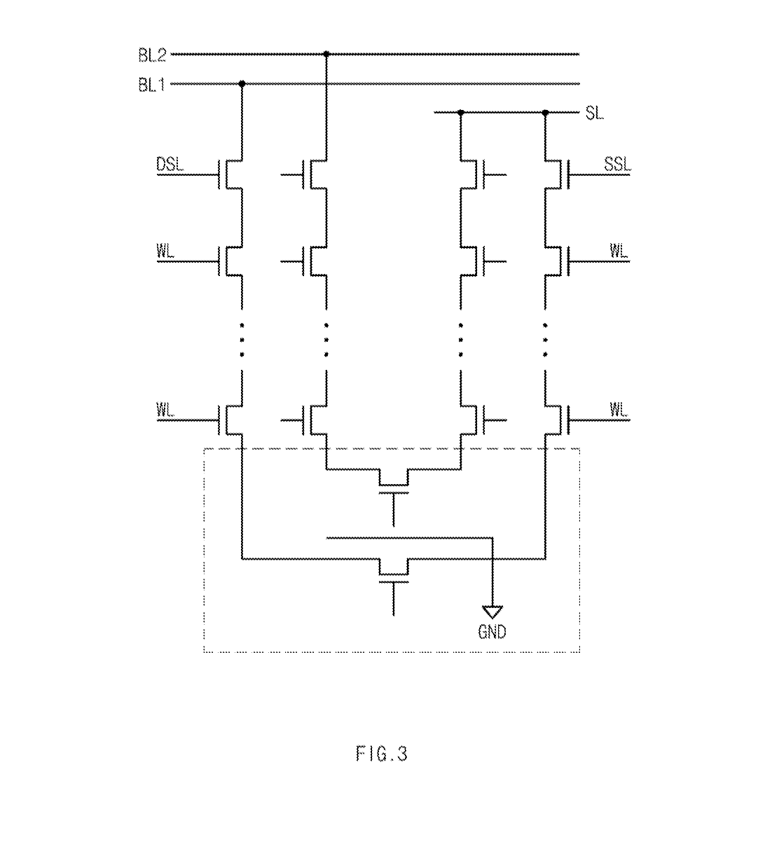

FIG. 3 is a circuit diagram illustrating a semiconductor device according to an embodiment.

Referring to FIG. 3, a source selection line SSL, a plurality of word lines WL, and a drain selection line DSL stacked along a first channel may construct a first string. Further, a source selection line SSL, a plurality of word lines WL and a drain selection line DSL stacked along a second channel may construct a second string. In addition, each of the first string and the second string may be coupled to a corresponding one of bit lines BL1 and BL2. For example, the first string may be coupled to the first bit line BL1, and the second string may be coupled to the second bit line BL2. In addition, the first string and the second string may be coupled to the same source line SL.

The ground voltage (VSS) is applied between the first channel and the second channel, so that the coupling phenomenon generated between the first channel and the second channel is suppressed and the parasitic capacitance is reduced.

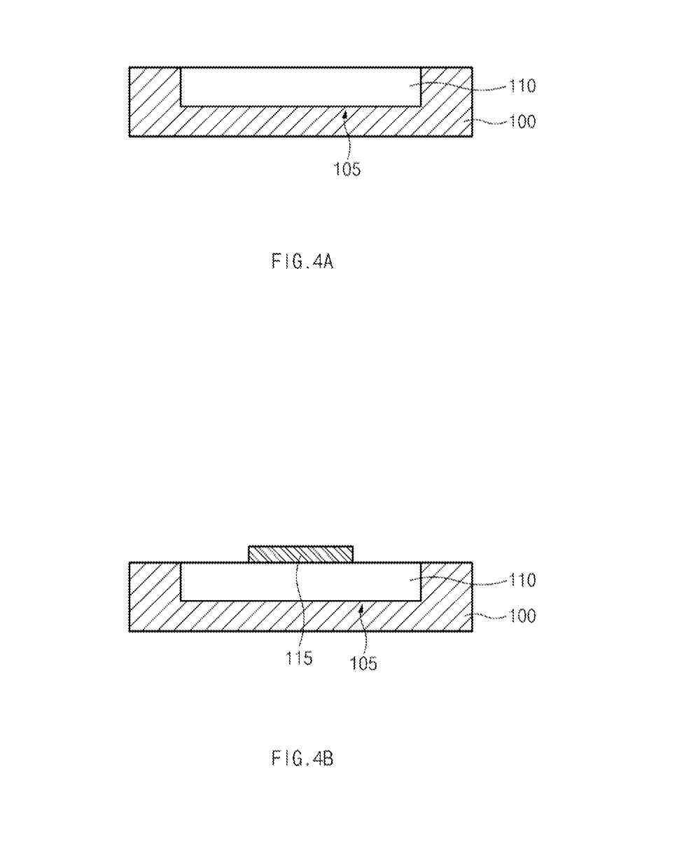

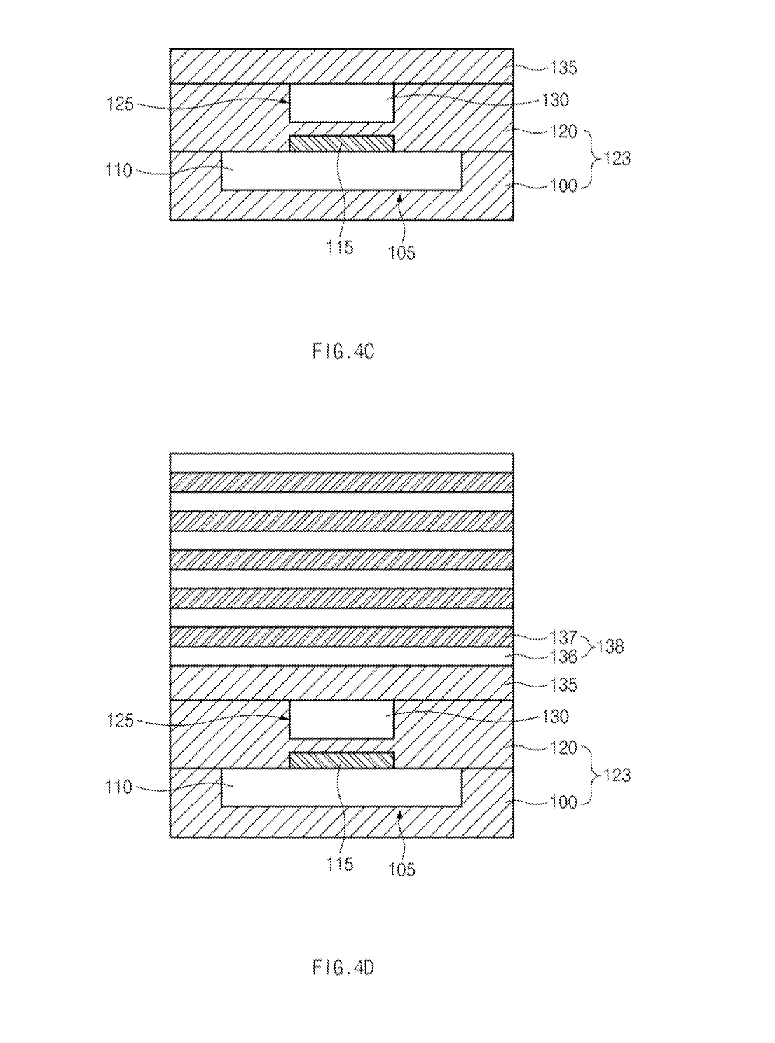

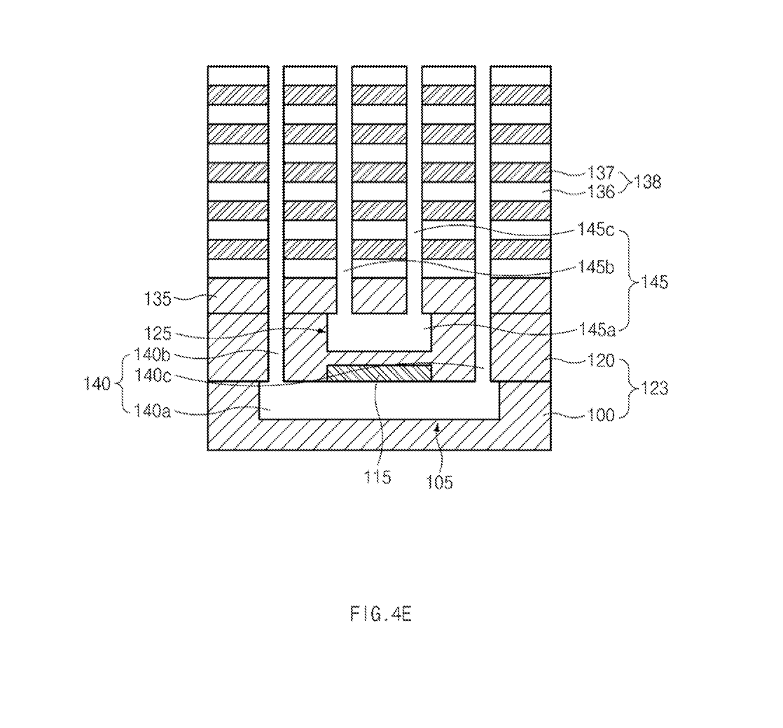

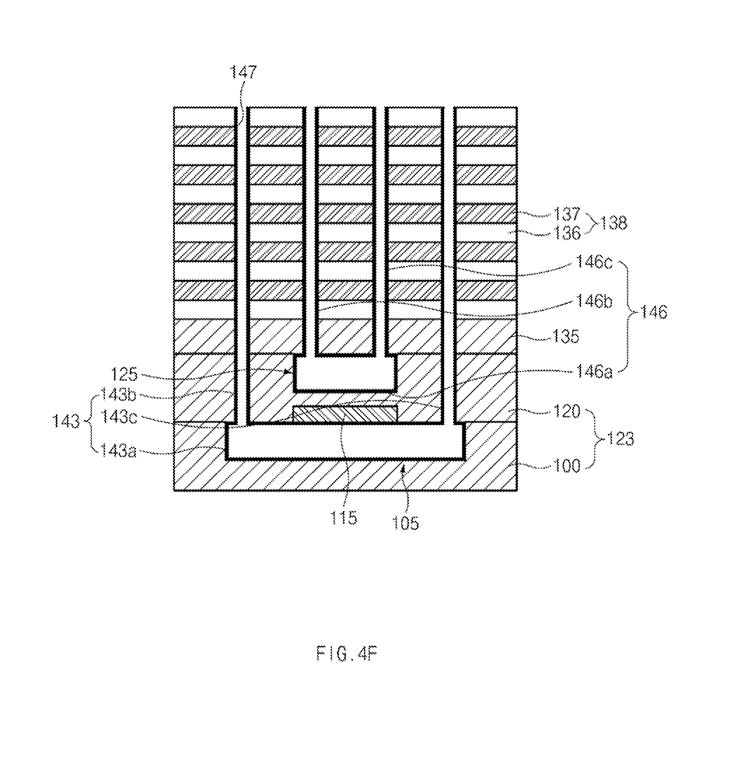

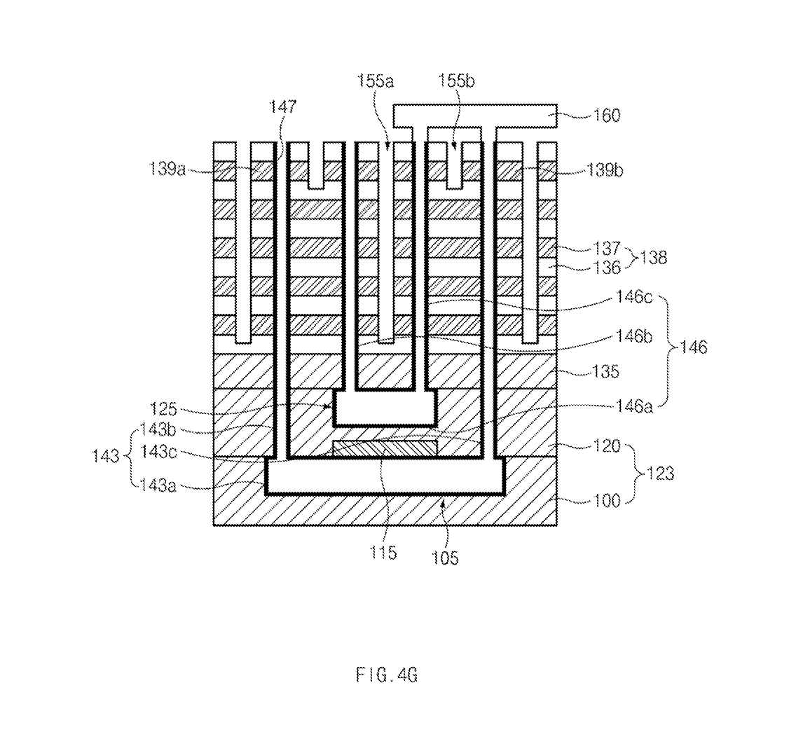

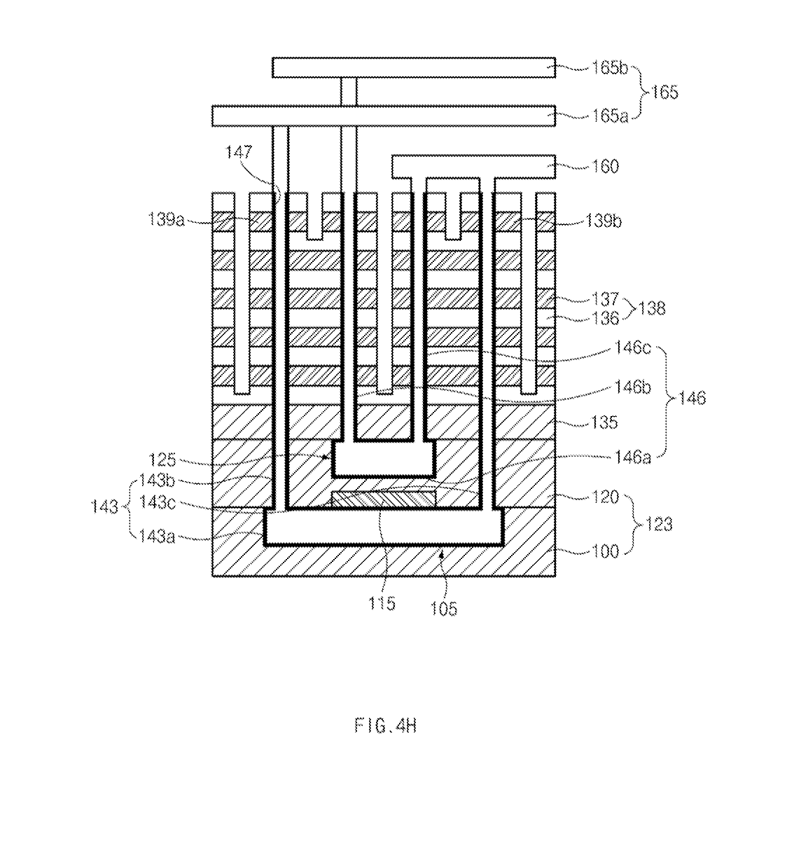

FIGS. 4A to 4H are cross-sectional views illustrating a method of fabricating a semiconductor device according to an embodiment.

Referring to FIG. 4A, a first conductive material (not shown) to be a pipe gate is formed over a semiconductor substrate (not shown) including a lower structure. Subsequently, the first conductive material is etched so that a first conductive pattern 100 is formed and a first trench 105 for forming a first pipe channel is formed. Thereafter, a first sacrificial film 110 is formed in the first trench 105. The first sacrificial film 110 may be formed of an oxide film, a nitride film, or a combination thereof.

Referring to FIG. 4B, an insulation material (not shown) is formed over an entire surface of a resultant structure including both the first conductive pattern 100 and the first sacrificial film 110. Thereafter, the insulation material is patterned to form an insulation pattern 115. The insulation pattern 115 may be formed of an oxide film or air-gap. The oxide film may be formed of a Spin On Dielectric (SOD) film or may also be formed of a Undoped Silicate Glass (USG) film, a Phosphorus Silicate Glass (PSG) film, a Boron Phosphorus Silicate Glass (BPSG) film, or a combination thereof.

Referring to FIG. 4C, a second conductive material (not shown) to be the pipe gate is formed over an entire surface of a resultant structure including the insulation pattern 115.

Subsequently, the second conductive material is etched so that a second conductive pattern 120 is formed and a second trench 125 for forming a second pipe channel is formed. The first conductive pattern 100 and the second conductive pattern 120 become a pipe gate 123. Thereafter, a second sacrificial film 130 is buried in the second trench 125. The second sacrificial film 130 may be formed of an oxide film, a nitride film, or a combination thereof.

Thereafter, a capping film 135 is formed over the second conductive pattern 120 and the second sacrificial film 130. The capping film 135 may be used as a protective film that prevents a channel film, a charge blocking film, a charge trap film, and a tunnel insulation film from being damaged by over-etching in a subsequent slit etching process.

Referring to FIG. 4D, an insulation film 136 is formed over the capping film 135, and a conductive material 137 is deposited over the insulation film 136, so as to form a word line 138. Thereafter, the insulation film 136 and the conductive material 137 are repeatedly deposited. As a result, a stacked structure of the word lines 138 is formed.

The word lines 138 may be repeatedly stacked a predetermined number of times corresponding to the number of memory cells coupled to one cell string. The conductive material 137 of the word line 138 may be formed of a doped polysilicon material, a polysilicon germanium material, a metal film, or a combination thereof. However, it should be noted that the conductive material 137 may also be form of any conductive material without departing from the scope or spirit of the present invention. The insulation film 136 may be used to isolate between vertically stacked memory cells, and may be formed of a silicon oxide film, a silicon nitride film, or a combination thereof.

Referring to FIG. 4E, the insulation film 136, the conductive material 137, the capping film 135, and the second conductive pattern 120 are sequentially etched, so that side channel regions for forming a source side channel and a drain side channel are formed. In this case, a first drain side channel region 140b and a first source side channel region 140c are respectively coupled to both sides of the first trench 105. In addition, a second drain side channel region 145b and a second source side channel region 145c are coupled to both sides of the second trench 125. The first drain side channel region 140b and the first source side channel region 140c coupled to the first trench 105 may be formed more deeply than the second drain side channel region 145b and the second source side channel region 145c coupled to the second trench 125. The first drain side channel region 140b, the first source side channel region 140c, the second drain side channel region 145b, and the second source side channel region 145c may be simultaneously formed, or may be formed by different processes.

The first sacrificial film 110 and the second sacrificial film 130 exposed by the side channel regions are removed, so that a first pipe channel region 140a and a second pipe channel region 145a are formed. As a result, a first channel region 140 including the first pipe channel region 140a, the first drain side channel region 140b and the first source side channel region 140c, and a second channel region 145 including the second pipe channel region 145a, the second drain side channel region 145b and the second source side channel region 145c, are formed in a U-shape, and the insulation pattern 115 is disposed between the first channel region 140 and the second channel region 145 that are vertically adjacent to each other.

Referring to FIG. 4F, a channel film 147 is formed along inner walls of the first channel region 140 and the second channel region 145.

As the channel film 147 is formed, a first channel 143 including a first pipe channel 143a, a first drain side channel 143b, and a first source side channel 143c is completed, and a second channel 146 including a second pipe channel 146a, a second drain side channel 146b and a second source side channel 146c is also completed.

The channel film 147 may include a blocking layer, a charge trap layer, and a tunneling layer that are respectively formed of an oxide film, a nitride film, and an oxide film.

The blocking layer may prevent movement of charges originating from a nitride film that acts as the charge trap layer. The oxide film acting as the blocking layer may be formed by depositing an oxide material using a Chemical Vapor Deposition (CVD) method. For example, the oxide film may be formed of a high-K material, for example, aluminum oxide (Al₂O₃), hafnium oxide (HfO₂), zirconium dioxide (ZrO₂), hafnium aluminum oxide (HfAlO), hafnium silicon oxide (HfSiO), etc. After forming the oxide film, a Rapid Thermal Annealing (RTA) process is performed on the semiconductor substrate including the oxide film.

After forming the oxide film, the nitride film acting as the charge trap layer is deposited to a thickness ranging from approximately 10 Å to approximately 1000 Å. For example, the nitride film may be formed of a silicon nitride film or a polysilicon film. The nitride film may be formed by an Atomic Layer Deposition (ALD) method or Chemical Vapor Deposition (CVD) method. The oxide film acting as the tunneling layer may be formed of a silicon oxide nitride (SION) by performing a deposition process under a mixed atmosphere of oxygen and nitrogen. In addition, after forming the oxide film, the oxide film is annealed under an atmosphere of nitric oxide (NO) gas or nitrous oxide (N₂O) gas, so that the quality of the oxide film may be improved.

Referring to FIG. 4G, the insulation films 136 and the conductive materials 137 are etched to form a plurality of slits needed for isolation of each word line.

A first slot 155a may be located outside of the first source side channel 143c and the first drain side channel 143b of the first channel 143, and may also be disposed between the second source side channel 146c and the second drain side channel 146b of the second channel 146. The first slot 155a may be formed to isolate a drain selection line (DSL) and a source selection line (SSL) contained in one string from each other, and may also be formed to isolate the word lines 138 from each other. The first slit 155a may be formed to expose the insulation film 136 deposited over the capping film 135.

In addition, a second slit 155b may be disposed between the first drain side channel 143b and the second drain side channel 146b, so as to isolate drain selection lines (DSLs) 139a from each other. Further, the second slit 155b may be disposed between the first source side channel 143c and the second drain side channel 146c, so as to isolate source selection lines (SSLs) 139b from each other. The second slit 155b may be formed by etching the insulation film 136 and the conductive material 137 that are formed at an uppermost portion. By this etching process, the drain selection line (DSL) 139a and the source selection line (SSL) 139b, which are isolated from each other, are formed over the word lines.

Referring to FIG. 4H, source lines 160 extending parallel to the word lines 138 are formed over the source selection lines (SSLs) 139b. The source lines 160 are coupled to the first source side channel 143c of the first channel 143 and the second source side channel 146c of the second channel 146.

Bit lines 165 extending parallel to the direction X1-X1′ or X2-X2′ are formed over the source lines 160. The first channel 143 and the second channel 146 are coupled to a corresponding one of the bit lines 165. For example, the first drain side channels 143b of the first channels 143 may be coupled to a first bit line 165a, and the second drain side channels 146b of the second channels 146 may be coupled to a second bit line 165b.

As described above, the insulation pattern 115 is inserted between vertically adjacent pipe channels, so that the coupling phenomenon generated between the first pipe channel 140a and the second pipe channel 145a is suppressed and the parasitic capacitance is reduced.

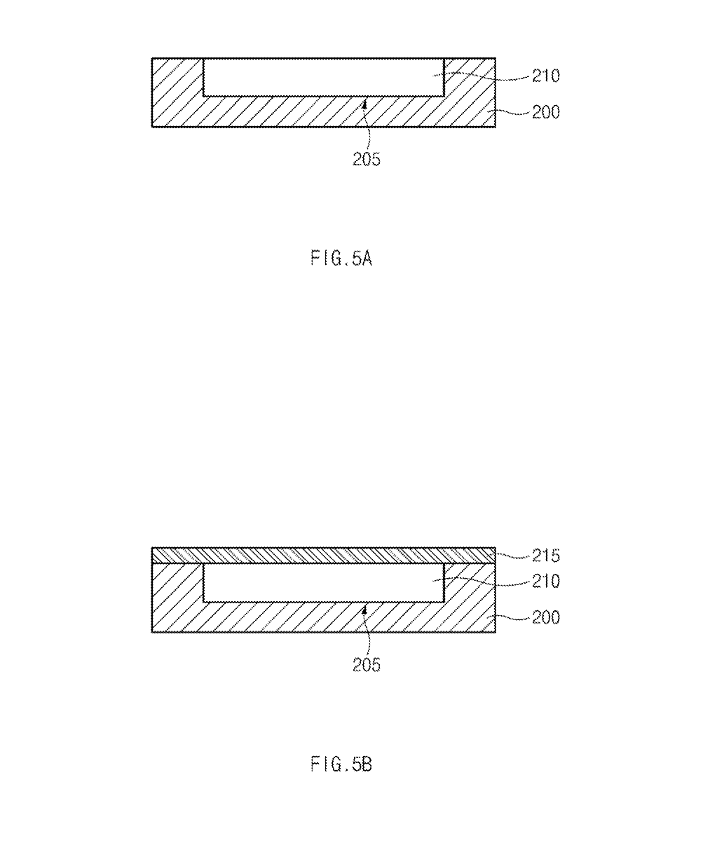

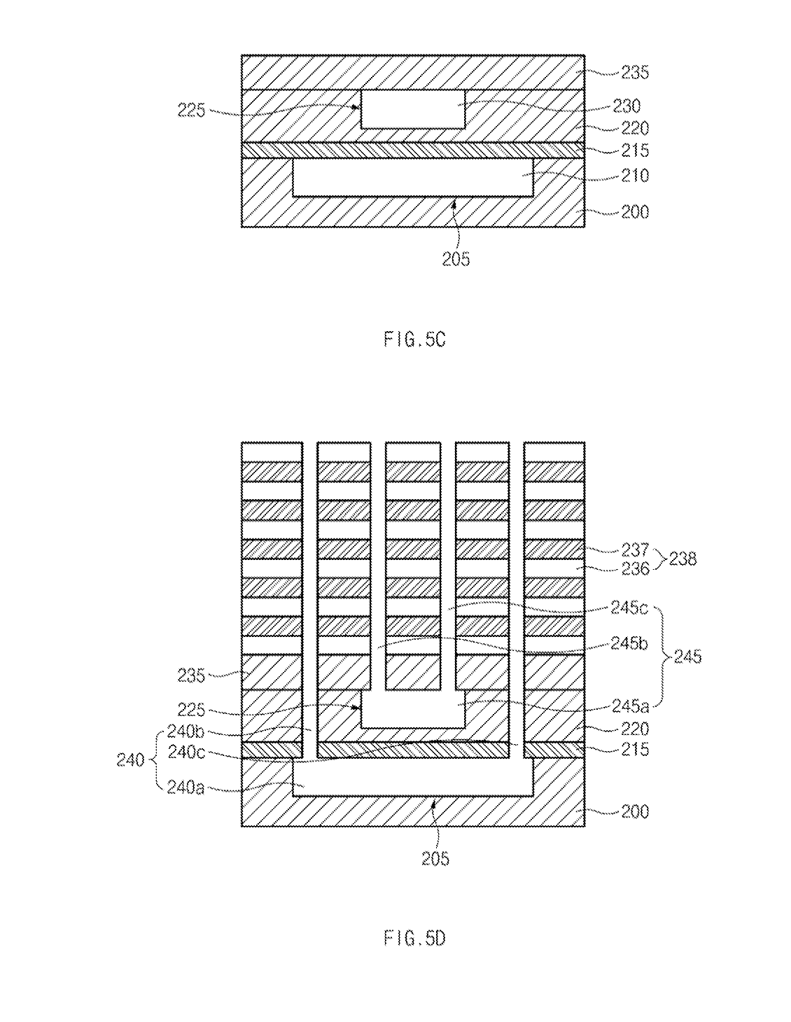

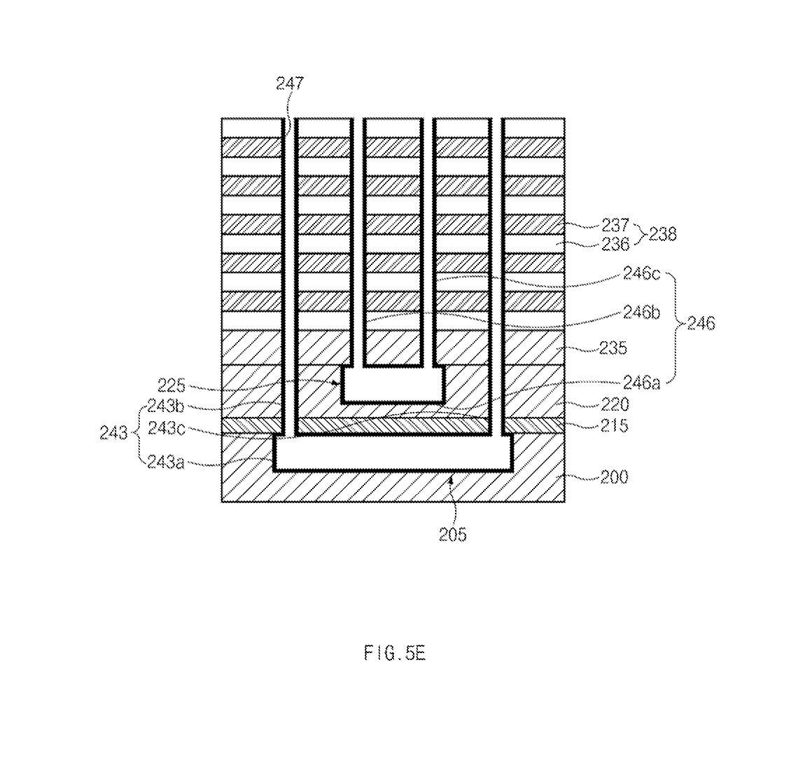

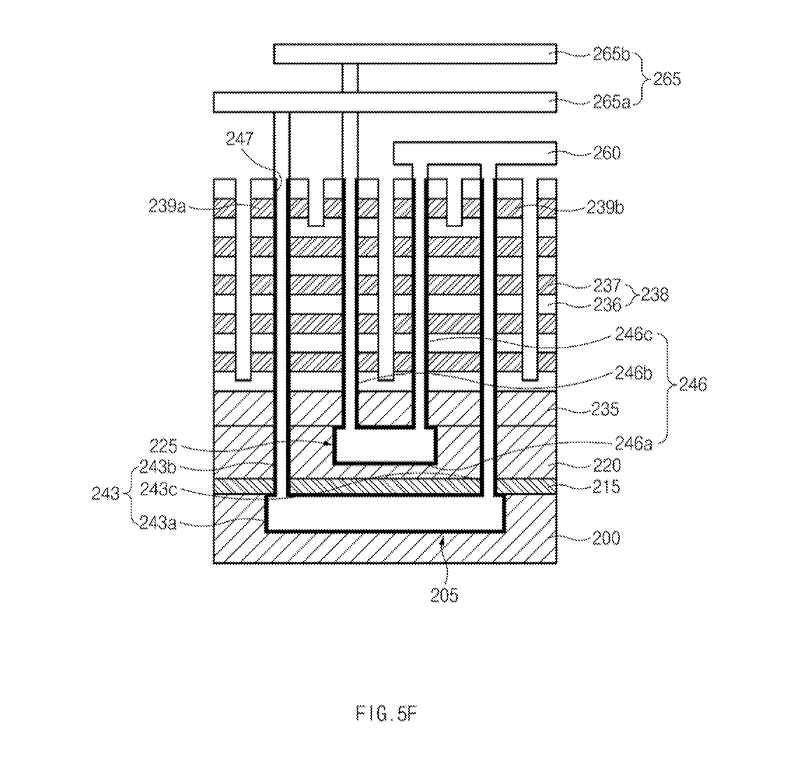

FIGS. 5A to 5F are cross-sectional views illustrating a method of fabricating a semiconductor device according to another embodiment.

Referring to FIG. 5A, a first conductive material (not shown) to be a pipe gate is formed over a semiconductor substrate (not shown) including a lower structure. The first conductive material is etched so that a first conductive pattern 200 is formed and a first trench 205 for forming a first pipe channel is formed. A first sacrificial film 210 is formed in the first trench 205.

Referring to FIG. 5B, an insulation film 215 is deposited over an entire surface of a resultant structure including the first sacrificial film 210 and the first conductive pattern 200. The insulation film 215 may also be formed of an oxide film or an air-gap.

Subsequent processes are carried out in the same order as in FIGS. 4A to 4F except that the insulation film 215 is not patterned but formed as a single layer at the same region as the pipe gate and, as such, a detailed description thereof will be briefly described.

Referring to FIG. 5C, a second conductive material (not shown) to be the pipe gate is formed over the insulation film 215. The second conductive material is etched so that a second conductive pattern 220 is formed and a second trench 225 for forming a second pipe channel is formed. A second sacrificial film 230 is formed in the second trench 225. Subsequently, a capping film 235 is formed over the second sacrificial film 230 and the second conductive material 220.

Referring to FIG. 5D, an insulation film 236 is formed over the capping film 235, and a conductive material 237 is deposited over the insulation film 236, to form a word line 238. Thereafter, the insulation film 236 and the conductive material 237 are repeatedly deposited. As a result, a stacked structure of the word lines 238 is formed.

Thereafter, the insulation film 236, the conductive material 237, the capping film 235, the second conductive pattern 220, and the insulation film 215 are sequentially etched, so that a first drain side channel region 240b and a first source side channel region 240c are formed to expose the first sacrificial film 210 of the first trench 205. In addition, a second drain side channel region 245b and a second source side channel region 245c are formed to expose the second sacrificial film 230 of the second trench 225.

Not only the first sacrificial film 210 exposed by the first drain side channel region 240b and the first source side channel region 240c, but also the second sacrificial film 230 exposed by the second drain side channel region 245b and the second source side channel region 245c is removed, so as to form a first pipe channel region 240a and a second pipe channel region 245a. As a result, a first channel region 240 including the first pipe channel region 240a, the first drain side channel region 240b and the first source side channel region 240c, and a second channel region 245 including the second pipe channel region 245a, the second drain side channel region 245b and the second source side channel region 245c, are formed in a U-shape, and the insulation film 215 is disposed between the first channel region 240 and the second channel region 245 that are vertically adjacent to each other.

Referring to FIG. 5E, a channel film 247 is formed along inner walls of the first channel region 240 and the second channel region 245.

As the channel film 247 is formed, a first channel 243 including a first pipe channel 243a, a first drain side channel 243b, and a first source side channel 243c is completed, and a second channel 246 including a second pipe channel 246a, a second drain side channel 246b and a second source side channel 246c is also completed.

Referring to FIG. 5F, a plurality of slits are formed to isolate the word lines 238 from each other. By this etching process, a drain selection line (DSL) 239a and a source selection line (SSL) 239b that are isolated from each other are formed over the word lines 238.

Subsequently, source lines 260 extending parallel to the word line 238 are formed over the source selection lines (SSLs) 239b. The source lines 260 are coupled to the first source side channel 243c of the first channel 243 and the second source side channel 246c of the second channel 246.

Bit lines 265 extending parallel to the direction X1-X1′ or X2-X2′ are formed over the source lines 260. In this case, the first drain side channels 243b of the first channels 243 may be coupled to a first bit line 265a, and the second drain side channels 246b of the first drain side channels 246 may be coupled to a second bit line 265b.

As described above, the insulation film 215 is inserted between vertically adjacent pipe channels, so that the coupling phenomenon generated between the first pipe channel 243a and the second pipe channel 246a may be suppressed and parasitic capacitance may be reduced.

As is apparent from the above description, a semiconductor device and the method of fabricating the same according to the embodiments insert an insulation material between vertically adjacent pipe channels, and reduce parasitic capacitance by suppressing the coupling phenomenon generated between pipe channels.

Those skilled in the art will appreciate that embodiments of the present disclosure may be carried out in other ways than those set forth herein without departing from the spirit and essential characteristics of these embodiments. The above embodiments are therefore to be construed in all aspects as illustrative and not restrictive.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a pipe gate;
a plurality of word lines vertically stacked over the pipe gate;
a first channel including a first pipe channel buried in the pipe gate, and a first side channel coupled to both sides of the first pipe channel by passing through the word lines;
a second channel including a second pipe channel buried in the pipe gate and disposed over the first pipe channel, and a second side channel coupled to both sides of the second pipe channel by passing through the word lines; and
an insulation pattern disposed between the first pipe channel and the second pipe channel, which are vertically adjacent from each other.

2. The semiconductor device according to claim 1, wherein the insulation pattern extends parallel to the word lines.

3. The semiconductor device according to claim 1, wherein the insulation pattern is formed over an entire region of the pipe gate.

4. The semiconductor device according to claim 1, wherein the first pipe channel and the second pipe channel are arranged in a manner such that the center point of the first pipe channel and the center point of the second pipe channel are offset from each other.

5. The semiconductor device according to claim 1, wherein the first pipe channel and the second pipe channel have different critical dimension (CD) values in a direction of a major axis.

6. The semiconductor device according to claim 1, further comprising:
a source selection line and a drain selection line formed over the word lines.

7. The semiconductor device according to claim 6, further comprising:
a source line coupled to the source selection line at an upper portion of the source selection line.

8. The semiconductor device according to claim 7, further comprising:
a bit line formed over the source line.

9. The semiconductor device according to claim 1, wherein the first side channel disposed at one side of the first channel and the second side channel disposed at one side of the second channel are coupled to different bit lines.

10. The semiconductor device according to claim 1, wherein the first side channel disposed at the other side of the first channel and the second side channel disposed at the other side of the second channel are coupled to a source line.

11. The semiconductor device according to claim 1, wherein the insulation pattern is formed of an oxide film or an air-gap.

12. The semiconductor device according to claim 1, wherein the word lines are formed by repeatedly stacking an insulation film and a conductive film.
